(19) United States
(12) Patent Application Publication
(10) Pub. No.: US 2013/0237053 A1
(43) Pub. Date: Sep. 12, 2013

(54) FILM FORMING METHOD AND FILM FORMING APPARATUS

(71) Applicants: Tadahiro Ishizaka, Yamanashi (JP); Takashi Sakuma, Yamanashi (JP); Tatsuo Hatano, Yamanashi (JP); Osamu Yokoyama, Yamanashi (JP); Atsushi Gomi, Yamanashi (JP); Chiaki Yasumuro, Yamanashi (JP); Toshihiko Fukushima, Yamanashi (JP); Hiroyuki Toshima, Yamanashi (JP); Masaya Kawamata, Yamanashi (JP); Yasushi Mizusawa, Yamanashi (JP); Takara Kato, Yamanashi (JP)

(72) Inventors: Tadahiro Ishizaka, Yamanashi (JP); Takashi Sakuma, Yamanashi (JP); Tatsuo Hatano, Yamanashi (JP); Osamu Yokoyama, Yamanashi (JP); Atsushi Gomi, Yamanashi (JP); Chiaki Yasumuro, Yamanashi (JP); Toshihiko Fukushima, Yamanashi (JP); Hiroyuki Toshima, Yamanashi (JP); Masaya Kawamata, Yamanashi (JP); Yasushi Mizusawa, Yamanashi (JP); Takara Kato, Yamanashi (JP)

(73) Assignee: Tokyo Electron Limited, Tokyo (JP)

(21) Appl. No.: 13/876,682

(22) PCT Filed: Sep. 26, 2011
(86) PCT No.: PCT/JP2011/071892

§ 371 Date: May 28, 2013

(30) Foreign Application Priority Data
Sep. 28, 2010 (JP) 2010-217895

(51) Int. Cl. H01L 21/768; H01J 37/34

(52) U.S. Cl. CPC H01L 21/768; H01J 37/34
USPC 438/642; 204/298.06

(57) ABSTRACT

A film forming method which generates metal ions from a metal target with a plasma in a processing chamber and attracts the metal ions with a bias to deposit a metal thin film on a target object wherein trenches are formed. The method includes: generating metal ions from a target and attracting the metal ions into a target object with a bias to form a base film in a trench; ionizing a rare gas with the bias in a state where no metal ion is generated and attracting the generated ions into the target object to etch the base film; and plasma sputtering the target to generate metal ions and attracting the metal ions into the object with a high frequency power for bias to deposit a main film as a metal film, while reflowing the main film by heating.

### FIELD OF THE INVENTION

The present invention relates to a film forming method and apparatus and more particularly to a film forming method and apparatus for effectively filling a metal in a recess formed in a target object such as a semiconductor wafer or the like by using a plasma.

### BACKGROUND OF THE INVENTION

Generally, in order to manufacture a semiconductor device, various processes such as film formation, pattern etching and the like are repetitively performed on a semiconductor wafer. A line width or a hole diameter has been getting smaller due to a demand for higher integration and further miniaturization of semiconductor devices. Both, a wiring resistance and a power consumption increase as semiconductor devices become further miniaturized. Therefore, in order to reduce the electrical resistance, a low costing copper (Cu), having a low electrical resistance tends to be used (see, e.g., Japanese Patent Application Publication No. 2000-077365). In the case of using Cu as a wiring material or a filling material, a Ta film, a Ti film, a TaN film, a TiN film, or the like is generally used as a barrier layer in consideration of the degree of adhesiveness to a base layer or the like.

In order to fill the recess with a metal, a barrier layer is firstly formed on an entire surface of a wafer, including the recess. Next, in a plasma sputtering apparatus, a thin seed layer made of Cu is formed on the barrier layer formed on the entire surface of the wafer, which includes the entire wall surface of the recess. Then, a Cu plating process is performed on the wafer surface, including the top surface of the Cu seed layer. As a result, the recess is completely filled with Cu. Thereafter, a residual Cu thin film on the wafer surface is removed by CMP (Chemical Mechanical Polishing) or the like (see, e.g., Japanese Patent Application Publication No. 2006-148075 (JP2006-148075A)).

The above-described metal filling process will be described with reference to FIGS. 1A to 1E. FIGS. 1A to 1E show a conventional process for filling a recess on a semiconductor wafer. A recess 4 corresponding to a via hole, a through hole, a groove (trench), or the like used for a Single Damascene process, a Dual Damascene process, a three-dimensional mounting process, or the like, is formed on a surface of an insulating layer 2, such as an interlayer insulating film formed of, e.g., a SiO₂ film, formed on the semiconductor wafer W. A wiring layer 6 as a base layer made of, e.g., Cu, is exposed on the bottom portion of the recess 4 (see FIG. 1A).

Specifically, the recess 4 includes a thin and long groove (trench) 4A having a recess-shaped cross section and a wiring structure such as a word line, a bit line, or the like, and a hole 4B formed at a part of the bottom portion of the groove 4A to connect an upper/lower word line or bit line. The hole 4B serves as a via hole or a through hole. Further, the wiring layer 6 is exposed on the bottom portion of the hole 4B. When the hole 4B is filled with a via plug or the like, an underlying wiring layer or a device such as a transistor or the like is electrically connected to a word line or the like buried in the groove 4A via a via plug or the like. The illustration of the underlying wiring layer or the device such as a transistor or the like is omitted. Due to the miniaturization of design rules, the recess 4 has a very small width or inner diameter of, e.g., multiples of nm, and an aspect ratio of, e.g., 2 to 4. The illustration of a diffusion barrier film, an etching stop film, or the like is omitted to simplify the configuration.

First, a barrier layer 8 having, e.g., a laminated structure of a TiN film and a Ti film, is substantially uniformly formed on the surface of the semiconductor wafer W including the inner surface of the recess 4 by using a plasma sputtering apparatus (see FIG. 1B). Then, a seed film 10 formed of a thin copper film as a metal film is formed on the entire surface of the wafer, including the inner surface of the recess 4, by using the plasma sputtering apparatus (see FIG. 1C). Thereafter, the copper plating process is performed on the wafer surface, so that the recess 4 is filled with a metal film 12 made of, e.g., Cu (see FIG. 1D). Next, the residual metal film 12, the residual seed film 10 and the residual barrier layer 8 on the wafer surface are removed by the CMP process or the like (see FIG. 1E).

Accordingly, when film formation is performed in a plasma sputtering apparatus, a film forming rate can be increased by facilitating the attraction of metal ions by applying a bias to the semiconductor wafer side. In this case, if the bias is excessively increased, the wafer surface is sputtered by ions of a rare gas, e.g., argon (Ar) gas that has been introduced into the apparatus to generate a plasma, and the deposited metal film can be removed. Therefore, the high frequency power for bias is not set to such a high level.

However, as described above, when the seed film 10 formed of a Cu film is formed as illustrated in FIG. 1C, ions are straightforwardly attracted into the recess due to anisotropy, which hinders the seed film from growing in the lower region of the sidewall in the recess 4. Therefore, if the film formation is carried out for a long period of time, until the seed film 10 forms a sufficient thickness on the sidewall, the seed film 10 is deposited particularly in the opening of the hole 4B so as to narrow the opening, and an overhang portion 14 projecting toward the opening of the recess 4 is formed. Hence, even if the recess 4 is filled with a metal film 12 such as a copper film by plating in a post process, the recess 4 may not be completely filled and a void 16 may be generated. In other words, the plating may be insufficient to completely fill the miniaturized recess.

### SUMMARY OF THE INVENTION

In order to solve the above problems, an excellent filling may be carried out by controlling an etching rate of a sputtering etching and a film forming rate by adjusting a high frequency power for bias applied to a mounting table, as described in JP2006-148075A. However, due to the recent demand for further miniaturization, the current film forming method cannot solve the above problems. The present invention has been conceived to effectively solve the above problems. In view of the above, the present invention provides a film forming method and a film forming apparatus capable of forming a metal film in a recess to prevent a generation of voids or the like.

The present inventors, having studied the film forming method using plasma sputtering, have conceived the present invention based on the fact that a generation of void or the like may be prevented by sufficiently forming a metal film in a bottom portion of a recess by causing the metal film to reflow.

In accordance with a first aspect of the present invention, there is provided a film forming method for depositing a metal thin film in a recess formed in a target object, which is mounted on a mounting table in a vacuum processing chamber, by attracting metal ions into the target object by supplying a high frequency power for bias to the mounting table to apply a bias to the target object, the metal ions being generated by ionizing a metal target by a plasma in the processing chamber. The method includes: a base film forming step of forming a base film containing the metal in the recess by attracting the metal ions into the target object with the bias; an etching step of etching the base film by attracting ions of a rare gas into the target object, the ions of the rare gas being generated by ionizing the rare gas by generating a plasma in a state where the metal ions are not generated while applying the bias to the target object; and a film forming reflow step of depositing a main film as a metal film by attracting the metal ions into the target object with the bias applied to the target object while ref lowing the main film by heating.

In accordance with a second aspect of the present invention, there is provided a film forming method for depositing a metal thin film in a recess formed in a target object, which is mounted on a mounting table in a vacuum processing chamber, by attracting metal ions into the target object by supplying a high frequency power for bias to the mounting table to apply a bias to the target object, the metal ions being generated by ionizing a metal target by a plasma in the processing chamber. The method including: a film forming and etching step of forming a base film containing the metal in the recess by attracting the metal ions into the target object with the bias while etching the base film; and a film forming reflow step of depositing a main film as a metal film by attracting the metal ions into the target object with the bias while ref lowing the main film by heating.

In accordance with a third aspect of the present invention, there is provided a film forming apparatus including: a vacuum processing chamber; a mounting table for mounting thereon a target object having a recess; a gas introducing unit for introducing a predetermined gas into the processing chamber; a plasma generation source for generating a plasma in the processing chamber; a metal target provided in the processing chamber to be ionized by the plasma; a high frequency power supply for supplying a high frequency power for bias to the mounting table; and an apparatus controller for controlling the entire apparatus to perform the film forming method described in the first or the second aspect.

### BRIEF DESCRIPTION OF THE DRAWINGS

FIGS. 1A to 1E show conventional processes for filling a recess of a semiconductor wafer.

FIG. 2 is a cross sectional view showing an example of a film forming apparatus in accordance with the present invention.

FIGS. 3A to 3G show processes for explaining a first embodiment of a film forming method in accordance with the present invention.

FIGS. 4A to 4C are enlarged views for explaining characteristic processes of the film forming method in accordance with the present invention.

FIG. 5 is a graph showing relationship between a high frequency power for bias and the amount of a Cu film formed on a top surface of a wafer.

FIG. 6 shows relationship between a filling result and a ratio Te/Td of a maximum film formation amount Td and an etching amount Te.

FIG. 7 is a graph showing a region where the ratio (Te/Td) is greater than or equal to 0.33.

FIG. 8A is a graph showing relationship between a high frequency power for bias according to changes in a DC power applied to a target and the ratio (Te/Td).

FIG. 8B is an enlarged view of FIG. 8A.

FIG. 9 presents a film formation and an etching process which is characteristics of a second embodiment of the film forming method in accordance with the present invention.

### DETAILED DESCRIPTION OF THE EMBODIMENTS

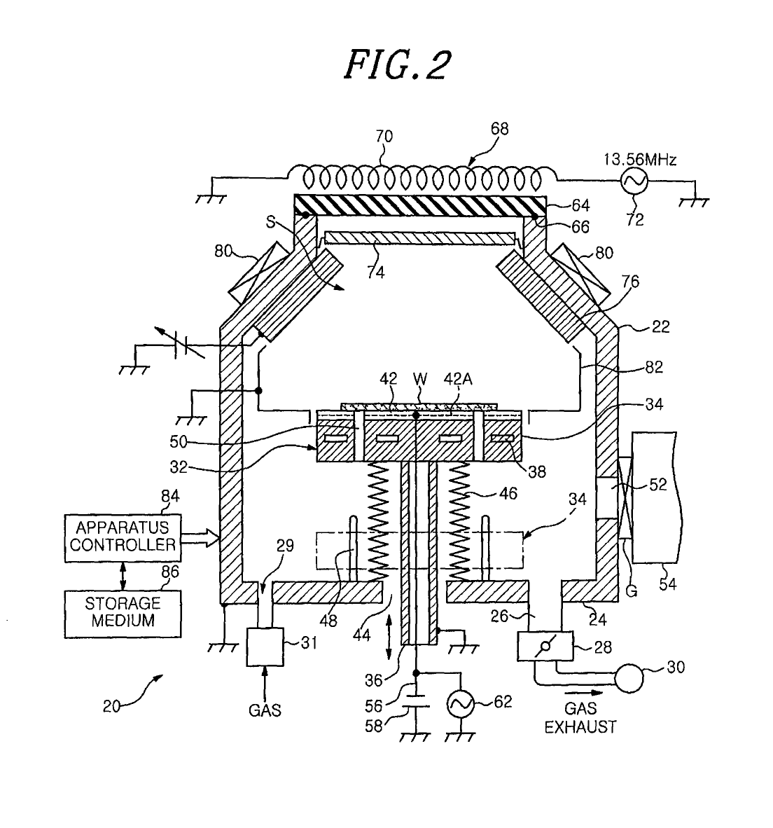

Hereinafter, embodiments of a film forming method and a film forming apparatus of the present invention will be described with reference to the accompanying drawings. FIG. 2 is a cross sectional view showing an example of the film forming apparatus in accordance with the present invention. Here, an ICP(Inductively Coupled Plasma) type plasma sputtering apparatus will be described as an example of a film forming apparatus.

As shown in FIG. 2, a film forming apparatus 20 includes a cylindrical processing chamber 22 made of, e.g., aluminum or the like. The processing chamber 22 is grounded. A gas exhaust port 26 is formed at a bottom portion 24 of the processing chamber 22, and a vacuum pump 30 is connected to the gas exhaust port 26 via a throttle valve 28 for pressure control. Accordingly, the processing chamber 22 can be vacuum exhausted. Provided at the bottom portion 24 of the processing chamber 22 is a gas inlet port 29 serving as a gas introducing unit for introducing a required predetermined gas into the processing chamber 22. A rare gas (e.g., Ar gas) as a plasma excitation gas or another required gas (e.g., N₂ gas) is supplied from the gas inlet port 29 through a gas control unit 31 including a flow rate controller, a valve, and the like.

A mounting table structure 32 for mounting thereon a semiconductor wafer W (hereinafter, referred to as “wafer”) to be processed is provided in the processing chamber 22. The mounting table structure 32 includes a circular plate-shaped mounting table 34, and a cylindrical hollow column 36 for supporting the mounting table 34. The column 36 is connected to a ground side, i.e., the column 36 is grounded. Thus, the mounting table 34 is also grounded. The mounting table 34 is made of a conductive material, e.g., aluminum alloy or the like, and a cooling jacket 38 is provided in the mounting table 34. By supplying a coolant through a coolant channel (not shown), a wafer temperature can be controlled.

A thin circular plate-shaped electrostatic chuck 42 made of a ceramic material, e.g., alumina or the like, which has therein an electrode 42A is provided on a top surface of the mounting table 34, so that the wafer W can be adsorbed thereonto by an electrostatic force. Further, the lower portion of the column 36 extends downward through an insertion through hole 44 formed at the central portion of the bottom portion 24 of the processing chamber 22. The column 36 is vertically movable by a driving mechanism (not shown), so that the entire mounting table structure 32 can be vertically moved.

An extensible and contractible metallic bellows 46 is provided so as to surround the column 36. The top end of the metallic bellows 46 is airtightly coupled to the bottom surface of the mounting table 34, and the bottom end of the metallic bellows 46 is airtightly coupled to the top surface of the bottom portion 24. Accordingly, the mounting table structure 32 can be vertically moved while maintaining the airtightness of the processing chamber 22.

Moreover, three (only two are shown in the illustrated example) support pins 48 stand upward on the bottom portion 24, and pin insertion through holes 50 are formed in the mounting table 34 so as to correspond with the support pins 48. Hence, when the mounting table 34 is lowered, the wafer W is supported by the top end portions of the support pins 48 which have been inserted through the pin insertion through holes 50. Accordingly, the wafer W can be transferred between the top end portions of the support pins 48 and a transfer arm (not shown) that enters the processing chamber 22 from the outside. Further, a loading/unloading port 52 for allowing the transfer arm to enter the processing chamber 22 is provided at a lower sidewall of the processing chamber 22, and an openable and closeable gate valve G is provided at the loading/unloading port 52. A vacuum transfer chamber 54 is provided on an opposite side of the gate valve G.

A chuck power supply 58 is connected to the electrode 42A of the electrostatic chuck 42 provided on the mounting table 34 via a power supply line 56. Therefore, the wafer W is adsorbed onto the electrostatic chuck 42 by the electrostatic force. Further, a high frequency power supply 62 for bias is connected to the power supply line 56 and a high frequency power for bias can be supplied to the electrode 42A of the electrostatic chuck 42 via the power supply line 56. The high frequency power has a frequency of, e.g., 13.56 MHz.

In addition, a transmitting plate 64 that is made of a dielectric material, e.g., aluminum oxide, and that transmits a high frequency, is airtightly provided at a ceiling portion of the processing chamber 22 via a sealing member 66 such as an O-ring or the like. Further, a plasma generation source 68, for converting a rare gas (e.g., Ar gas) into a plasma when the rare gas as a plasma generation gas is supplied into a processing space S in the processing chamber 22, is provided above the transmitting plate 64.

As for the plasma excitation gas, another rare gas, e.g., He, Ne, or the like may be used instead of Ar. Specifically, the plasma generation source 68 has an induction coil 70 that is disposed to correspond to the transmitting plate 64. A high frequency power supply 72 of, e.g., 13.56 MHz, for plasma generation is connected to the induction coil 70, so that the high frequency can be introduced into the processing space S via the transmitting plate 64.

A baffle plate 74 made of, e.g., aluminum, for diffusing the introduced high frequency is provided directly below the transmitting plate 64. A metal target 76 of, e.g., an annular shape having a cross section slanted inwardly (i.e., having a truncated circular cone shape) is provided below the baffle plate 74 so as to surround an upper portion of the processing space S. The metal target 76 is connected to a variable DC power supply 78 for target which supplies a voltage for attracting Ar ions. An AC power supply may be used instead of the DC power supply 78.

A magnet 80 for generating a magnetic field in a space surrounded by the metal target 76 is provided at an outer peripheral side of the metal target 76. Here, the metal target 76 is made of, e.g., Cu, and the Cu target 76 is sputtered by Ar ions in the plasma. Accordingly, metal atoms or metal atom groups of Cu are emitted. Most of the emitted metal atoms or metal atom groups of Cu are ionized while passing through the plasma.

A cylindrical protection cover member 82 made of, e.g., aluminum or copper, is provided below the metal target 76 so as to surround the processing space S. The protection cover member 82 is grounded while being connected to a ground side. Further, a lower portion of the protection cover member 82 is bent inward so as to be positioned near a side portion of the mounting table 34. In other words, the inner end portion of the protection cover member 82 surrounds the outer periphery of the mounting table 34.

Each component of the film forming apparatus 20 is connected to and controlled by an apparatus controller 84 formed of, e.g., a computer or the like. Specifically, the apparatus controller 84 controls operations of the high frequency power supply 62 for applying a bias, the high frequency power supply 72 for generating plasma, the variable DC power supply 78, the gas control unit 31, the throttle valve 28, the vacuum pump 30, and the like. Further, the program executed by the apparatus controller 84 is stored in a computer-readable storage medium 86 and read out by the apparatus controller 84. The storage medium 86 may be, e.g., a flexible disk, a Compact Disk (CD), a hard disk, a flash memory, a Digital Versatile Disk (DVD), or the like.

<Explanation of the Film Forming Method>

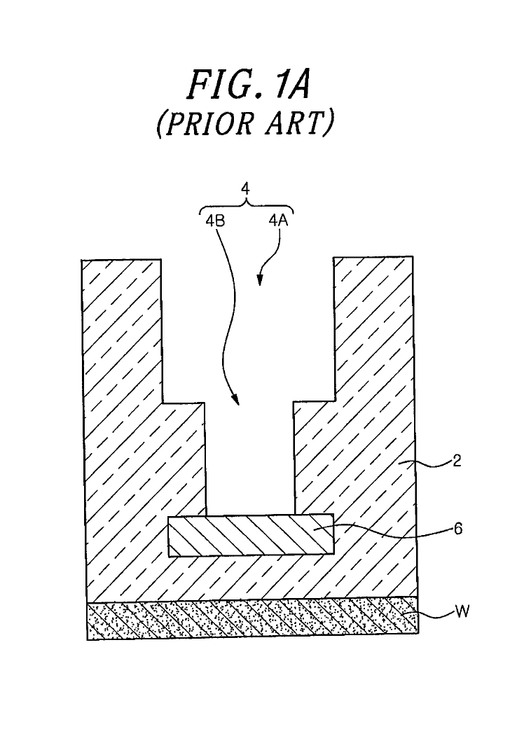

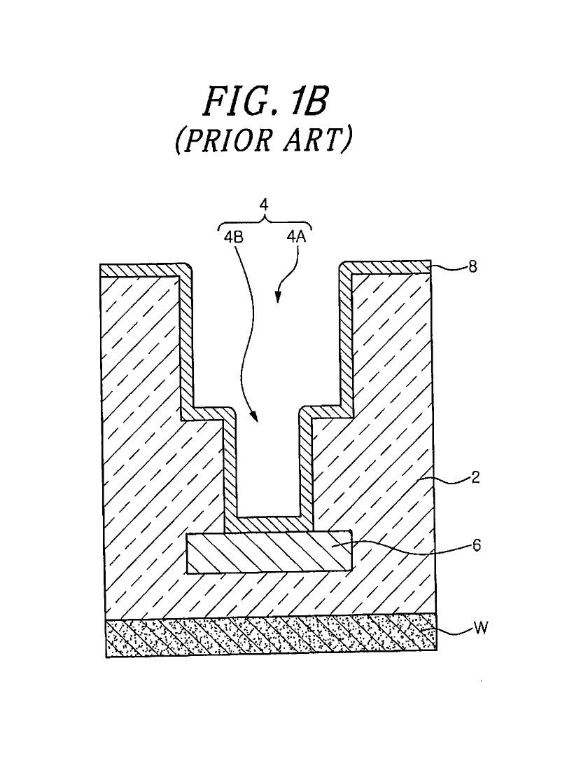

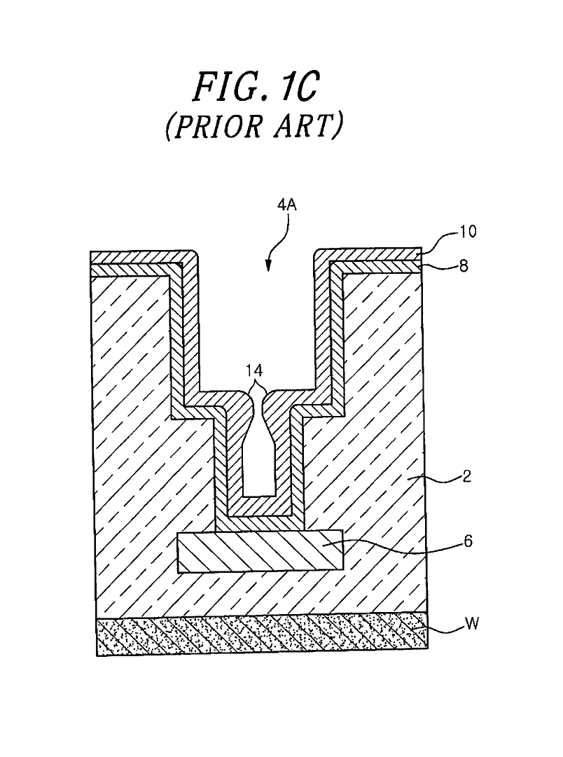

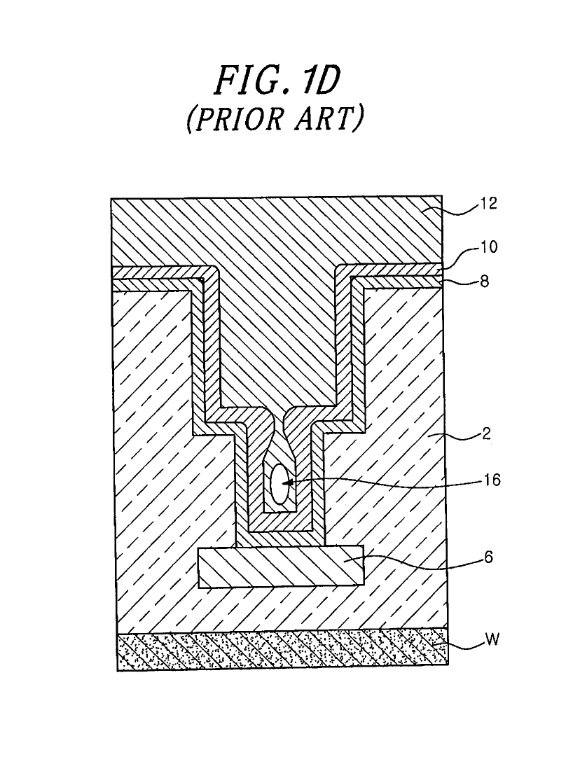

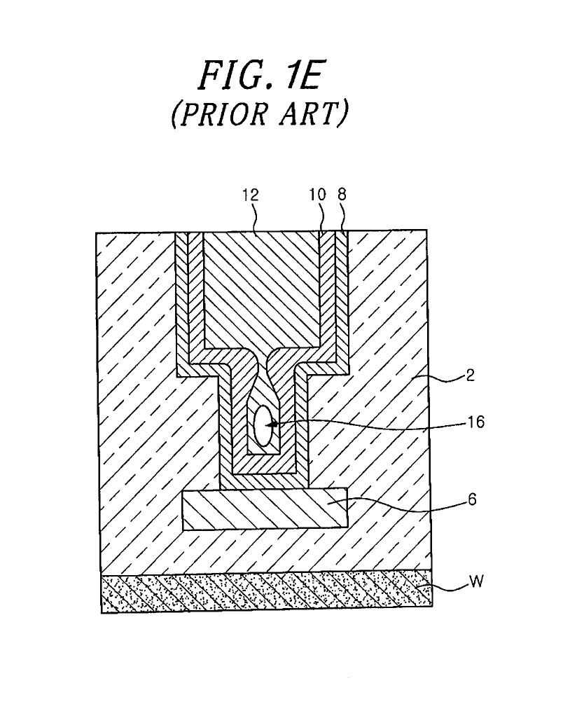

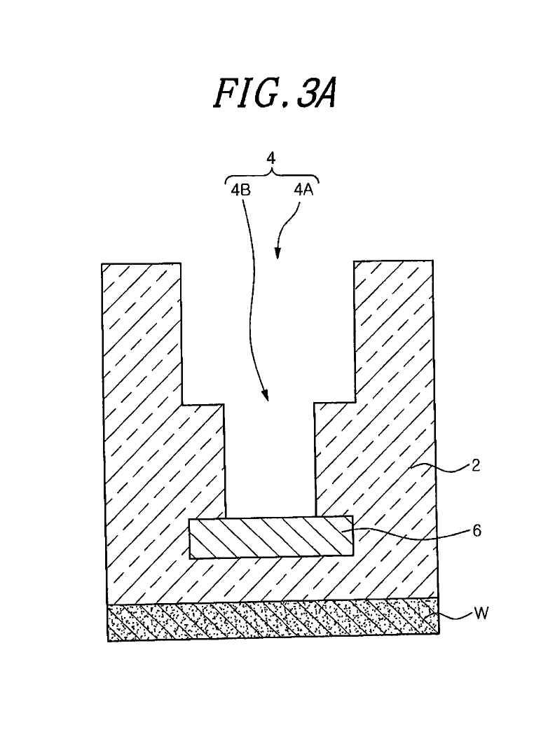

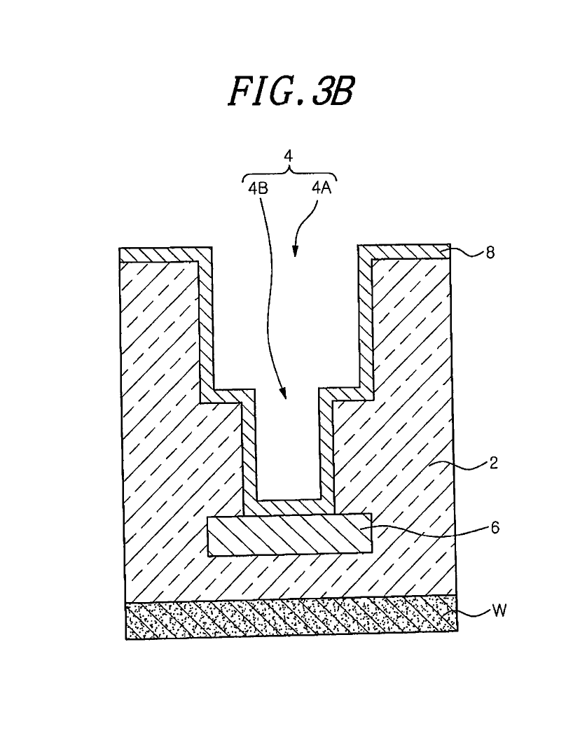

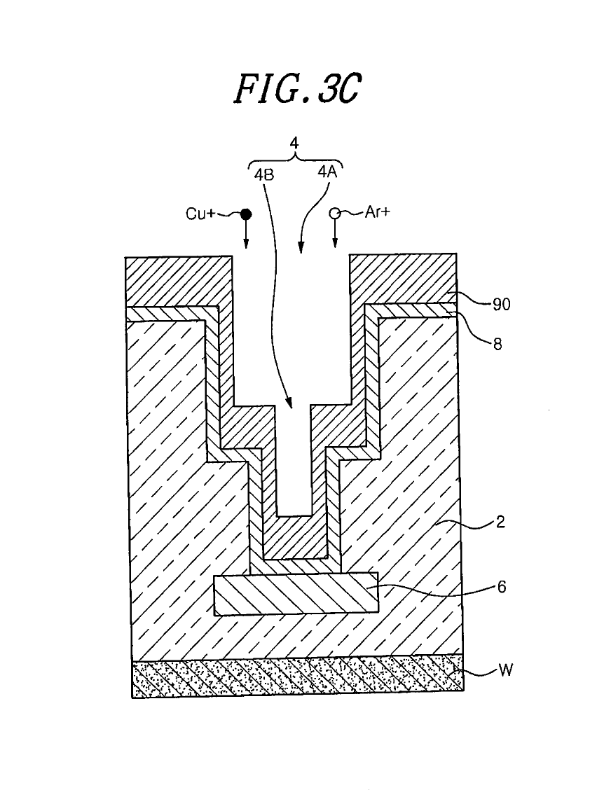

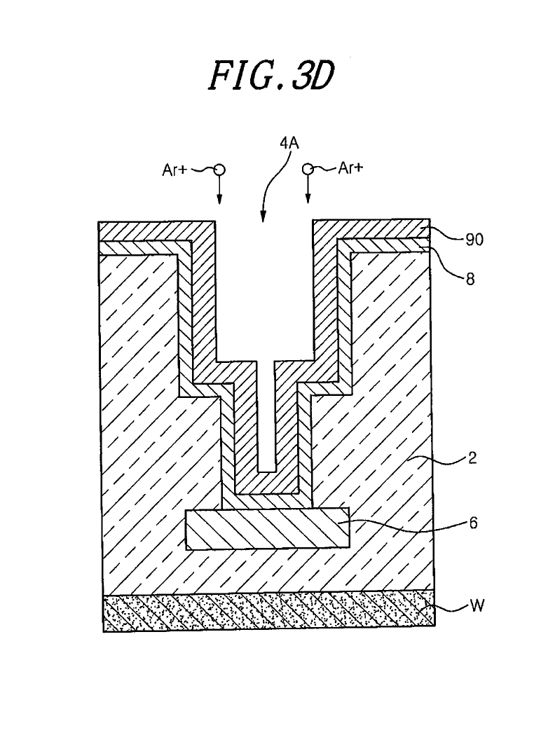

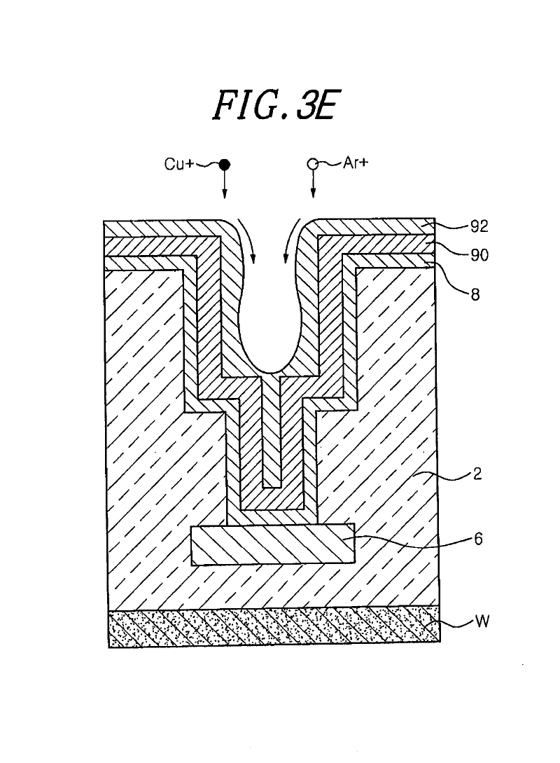

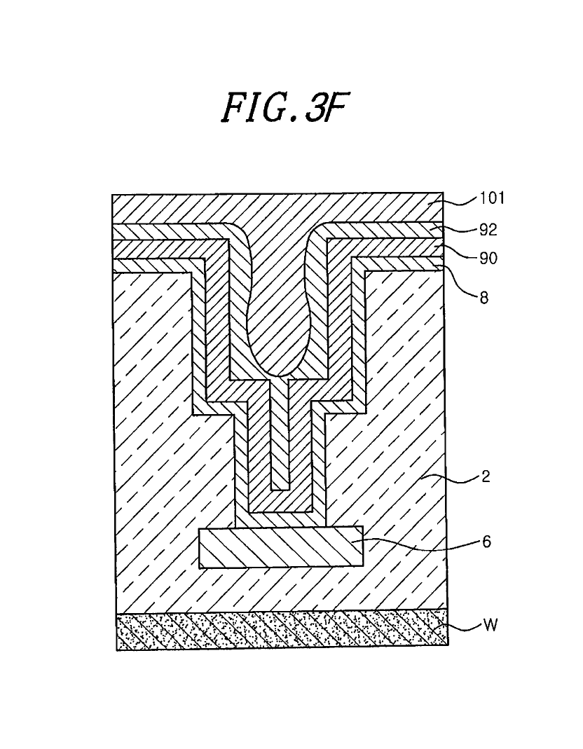

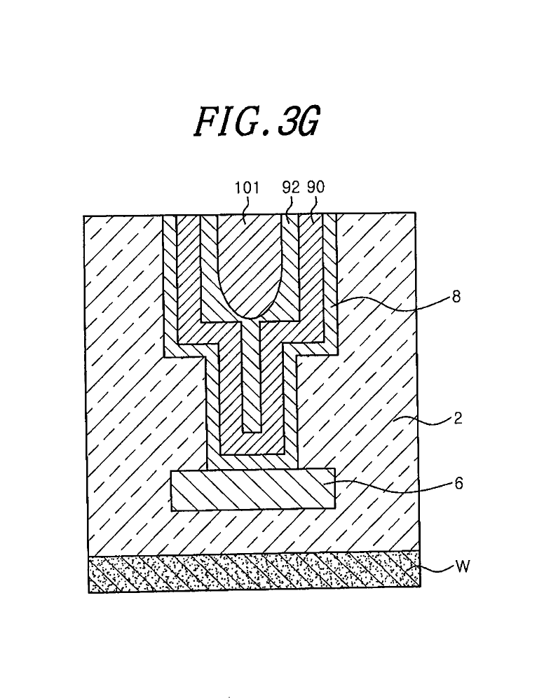

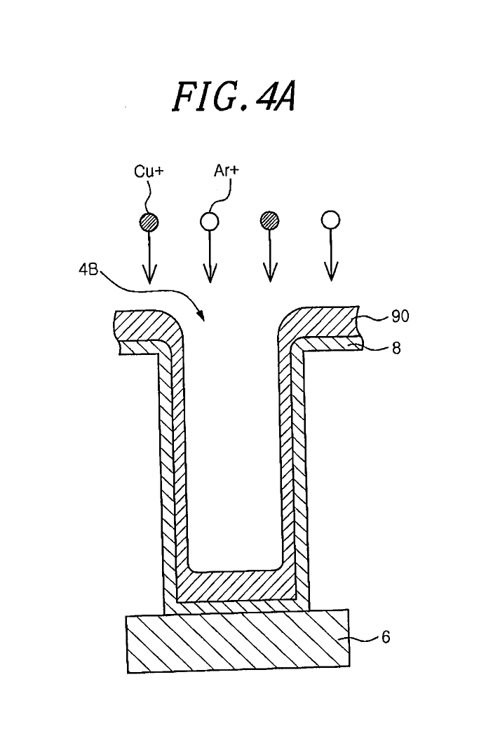

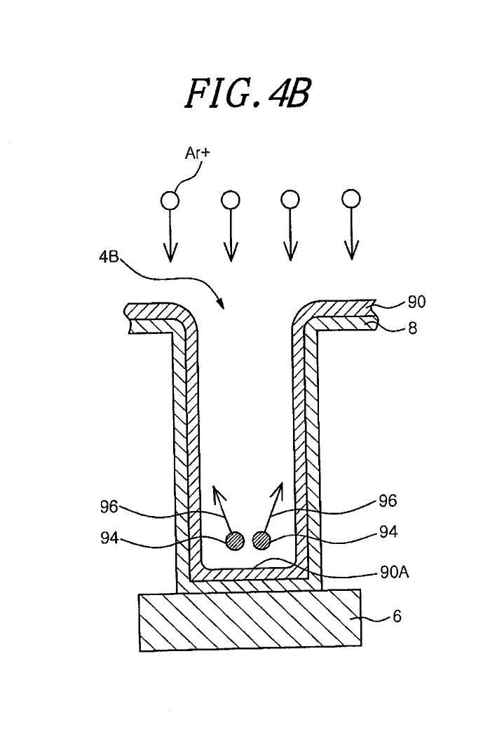

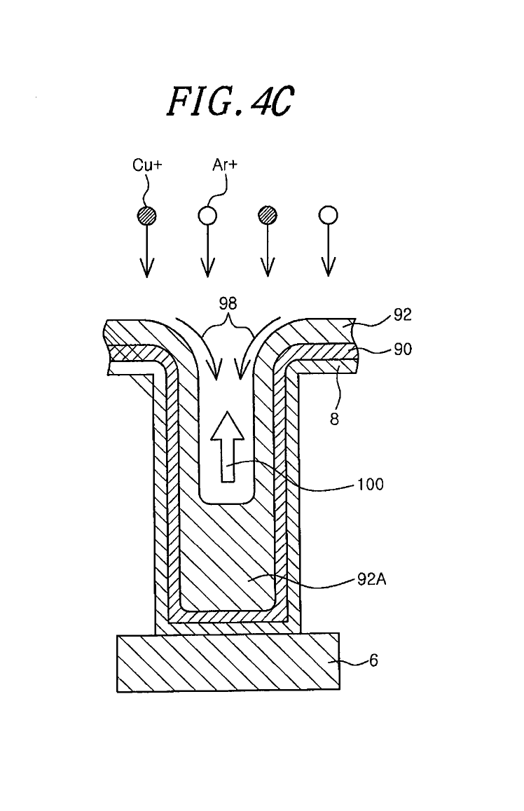

Hereinafter, an operation of the plasma film forming apparatus configured as described above will be described with reference to FIGS. 3A to 7. In FIGS. 3A to 4C, like reference numerals are used to denote like parts in FIG. 1.

As shown in FIG. 3A, the recess 4 corresponding to a via hole, a through hole, a groove (trench), or the like used for a Single Damascene process, a Dual Damascene process, a three-dimensional mounting process, or the like is formed on a surface of the insulating layer 2 such as an interlayer insulating film formed of, e.g., a SiO₂ film, formed on the wafer W. Further, the underlying wiring layer 6 made of, e.g., Cu, is exposed on the bottom portion of the recess 4.

Specifically, the recess 4 includes a thin and long groove (trench) 4A having a recess-shaped cross section which specifies a word line, a bit line, or the like, and a hole 4B formed at a part of the bottom portion of the groove 4A which specifies a plug for connecting an upper/lower word line or bit line. The hole 4B serves as a via hole or a through hole. Further, the wiring layer 6 is exposed on the bottom portion of the hole 4B. The wiring layer 6 is electrically connected to an underlying wiring layer (not shown) or a device such as a transistor (not shown) or the like. Due to the miniaturization of the design rules, the recess 4 has a very small width or inner diameter of, e.g., multiples of 10 nm, and an aspect ratio of, e.g., 2 to 4. The illustration of a diffusion barrier film, an etching stop film, or the like is omitted for simplification.

As shown in FIG. 3B, the barrier layer 8 having, e.g., a laminated structure of a TiN film and a Ti film, is substantially uniformly formed beforehand on the surface of the wafer W including the inner surface of the recess 4 by using a plasma sputtering apparatus or the like.

Next, the wafer W having the above-described structure is loaded into the film forming apparatus 20 shown in FIG. 2. The wafer W is mounted on the mounting table 34 and adsorbed onto the electrostatic chuck 42. First, under the control of the apparatus controller 84, by operating the gas control unit 31, Ar gas is introduced into the processing chamber 22 which has been evacuated to vacuum by the vacuum pump 30 while controlling the pressure in the processing chamber 22 to a predetermined level by adjusting the throttle valve 28. Thereafter, a DC power is applied from the variable DC power supply 78 to the metal target 76 and a high frequency power (plasma power) is supplied from the high frequency power supply 72 of the plasma generation source 68 to the induction coil 70.

Meanwhile, the apparatus controller 84 transmits an instruction to the high frequency power supply 62 and supplies a predetermined high frequency power for bias to the electrode 42a of the electrostatic chuck 42. In the processing chamber 22 controlled as described above, an Ar plasma is generated by the high frequency power supplied to the induction coil 70 and thus, Ar ions are generated. These ions are attracted by the DC voltage applied to the metal target 76 and collide with the metal target 76. Accordingly, the metal target 76 is sputtered, and the metal particles are emitted. At this time, the amount of metal particles emitted is controlled by controlling the DC power applied to the target 76.

Further, most of the metal atoms or the metal atom groups, which are the metal particles emitted from the sputtered metal target 76, are ionized while passing through the plasma. Therefore, the ionized metal ions and the unionized neutral metal atoms coexist in the metal particles and they are scattered downward. Particularly, the pressure in the processing chamber 22 is set to a relatively high level. Accordingly, the density of the plasma is increased, so that the metal particles can be ionized efficiently. The ionization rate at this time is controlled by the high frequency power supplied from the high frequency power supply 72.

Due to the high frequency power for bias applied to the electrode 42A of the electrostatic chuck 42, the ion sheath region having a thickness of several millimeters is formed above the wafer surface. When the metal ions are introduced into the ion sheath region, the metal ions are attracted toward the wafer W with a strong directivity to be accelerated thereto. Hence, the metal ions are deposited on the wafer W, thereby forming a metal thin film.

With the above-described operations, in the present embodiment, a base film formation step, of forming a base film 90 containing metal in a recess 4 by attracting metal ions generated in the film forming apparatus 20 toward the wafer W with a bias (see FIG. 3C); an etching step, of ionizing the rare gas by generating a plasma under the condition in which no metal ion is generated while applying a bias to the wafer to etch the base film 90 by attracting ions toward the wafer W (see FIG. 3D); and a film forming reflow step, of depositing a main film 92 formed of a metal film by attracting the metal ions toward the wafer W with the bias applied to the wafer while ref lowing the main film 92 by heating (see FIG. 3E) are carried out in that order. The FIGS. 4A to 4C show the steps corresponding to FIGS. 3C to 3E to schematically illustrate the enlarged views of the hole 4B.

First, as shown in FIG. 3C and FIG. 4A, in the base film formation step, a base film 90 formed of a Cu film is formed on the entire surface of the wafer W, including the inner surface of the recess 4, by using the above-described film forming method. When the base film 90 is formed, the high frequency power for bias is applied to the electrode 42A such that the amount of the Cu film formed on the top surface of the wafer W becomes maximized, as will be later described.

While the sputtering is being performed by the film forming apparatus 20, the metal ions and the Ar ions are simultaneously attracted to the surface of the wafer W with the bias. The metal ions act to the film formation and the Ar ions act to etch the deposited thin film. In other words, the metal ions and the Ar ions perform the opposite actions.

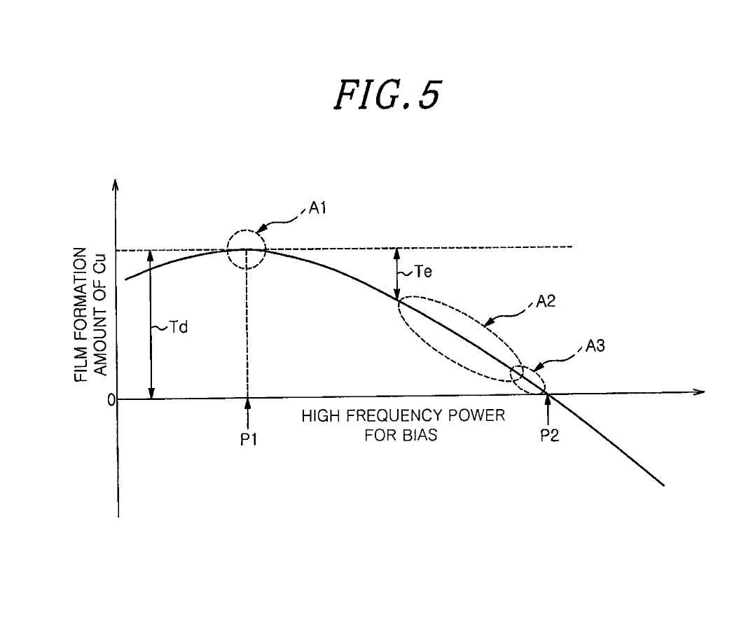

Accordingly, the amount of the thin film formed on the wafer surface is determined by the difference between the film forming rate by the metal ions and the etching rate of Ar ions. FIG. 5 shows relationship between the amount of the Cu film formed on the wafer surface and the high frequency power for bias. In other words, when the high frequency power for bias is increased from substantially zero, the film formation amount of the Cu film is increased as the high frequency power for bias is increased. The film formation amount of the Cu film becomes peak at a point P1. As the high frequency power for bias is increased further, the film formation amount of the Cu film is gradually decreased.

At a point P2, the etching rate of Ar ions and the film forming rate of the Cu ions become the same and thus, the film formation amount on the wafer surface becomes zero. If the high frequency power for bias is increased further, the Cu film formation is not carried out, whereas the base film 90 is gradually etched.

In the base film formation step, as described above, the base film 90 is formed with a high frequency power for bias which maximizes the film formation amount of the Cu film, i.e., a high frequency power for bias at the point P1 in FIG. 5 (or within a region Al including the point P1).

As a result, the downward directivity of the metal ions is increased. Therefore, a thick base film 90 is formed on a surface of the wafer which faces upward, i.e., the top surface of the wafer W, the bottom surface of the hole 4B, and the bottom surface of the groove 4A. In contrast, a thin base film is formed on a side surface of the groove 4A or a side surface of the hole 4B. Here, the film formation amount of the Cu film is, e.g., 30 nm.

The processing conditions in the base film forming step are described as follows.

The processing pressure is preferably in a range from 50 mTorr to 200 mTorr and more preferably in a range from 65 mTorr to 100 mTorr. Specifically, the processing pressure may be set to, e.g., 90 mTorr.

The high frequency power for plasma generation is preferably in a range from 3 kW to 6 kW and more preferably in a range from 4 kW to 5 kW. Specifically, the high frequency power for plasma generation may be set to, e.g., 4 kW.

The DC power applied to the target is preferably in a range from 4 kW to 20 kW and more preferably in a range from 8 kW to 12 kW. Specifically, the DC power to the target may be set to, e.g., 10 kW.

The high frequency power for bias is preferably in a range from 25 W to 300 W and more preferably in a range from 100 W to 200 W. Specifically, the high frequency power for bias may be set to, e.g. 200 W.

The wafer temperature is preferably in a range from 50° C. to 200° C., and more preferably in a range from 50° C. to 175° C. Specifically, the wafer temperature may be set to, e.g., 50° C.

Next, as shown in FIG. 3D and the FIG. 4B, in the etching step, the rare gas is ionized by generating a plasma under the condition in which no metal ion is generated and the base film 90 is etched by attracting the generated ions toward the wafer W with a bias applied to the wafer W. In the etching step, the etching of the base film 90 is mainly carried out. Specifically, the generation of Cu ions is prevented by setting the high frequency power for plasma generation and the DC power applied to the target 76 to zero.

The high frequency power for bias in the etching step is set to be larger than that in the base film formation step. Here, a capacitively coupled circuit of a high frequency is formed between the electrode 42A of the electrostatic chuck 42 and the protection cover member 82 to generate a plasma of Ar gas. As described above, Ar ions are attracted toward the wafer W and thus, the etching is carried out. Further, the processing pressure (pressure in the chamber) in the etching step is set to be lower than that in the base film formation step.

As a result of the etching, the thickness of the thick base film 90 deposited on the surface of the wafer W which faces upward, i.e., the top surface of the wafer W, the bottom surface of the hole 4B and the bottom surface of the groove 4A is reduced by etching. At this time, if the base film 90A deposited on the bottom surface of the fine hole 4B is etched by sputtering as more closely shown in FIG. 4B, Cu metal particles 94 generated at this time are scattered and deposited on the sidewall in the hole 4B as indicated by arrows 96. As a result, the thickness of the base film 90 deposited on the sidewall in the hole 4B is increased and the base film 90 of a sufficient thickness is formed on the sidewall portion.

The processing conditions in the etching step are described as follows.

The processing pressure is preferably in a range from 0.4 mTorr to 10 mTorr, and more preferably in a range from 1 mTorr to 2.5 mTorr. Specifically, the processing pressure may be set to, e.g., 2.5 mTorr.

The high frequency power for plasma generation is 0V, and the DC power supplied to the target is 0V.

The high frequency power for bias is preferably in a range from 1000 W to 3000 W, and more preferably in a range from 2000 W to 2500 W. Specifically, the high frequency power for bias may be set to, e.g., 2400 W.

The wafer temperature is preferably in a range from 25° C. to 200° C., and more preferably in a range from 50° C. to 100° C. Specifically, the wafer temperature may be set to, e.g., 50° C.

As described above, by setting the high frequency power for bias in the etching step to be higher than that in the base film formation step, the directivity of Ar ions is increased, and the etching can be more effectively performed. Further, by setting the processing pressure in the etching step to be higher than that in the base film formation step, the directivity of Ar ions is further increased, and the etching can be more effectively performed.

Next, as shown in FIG. 3E and FIG. 4C, in the film forming reflow step, the main film 92 formed of a metal film is deposited by attracting metal ions toward the wafer W and reflowed by heating. Specifically, Cu metal ions are generated by supplying the high frequency power for plasma generation and applying the DC power to the metal target 76 again so that the Cu film is formed and etched. More specifically, the main film 92 formed of a metal film such as a Cu film is formed, and the reflow of the Cu film is facilitated by increasing the wafer temperature to 25° C. to 200° C. with an ion energy by increasing the high frequency power for bias.

Therefore, the high frequency power for bias in the film formation step is set to be higher than that in the previous base film formation step. Specifically, the process is carried out with a high frequency power for bias within a wide region A2 in FIG. 5 which is positioned at a right side of the region A1 and at a left side of the point P2 where the etching rate and the film forming rate by Cu ions are substantially balanced. Further, the processing pressure in the film forming reflow step is set to be higher than that in the etching step.

Accordingly, the main film 92 formed of a Cu film deposited on the surface is soft and thus flows on the base film 90 deposited with a sufficient thickness on the sidewall of the hole 4B so as to be diffused into the hole 4B, as indicated by arrows 98 (see FIG. 4C). As a result, the main film 92A at the bottom portion of the hole 4B becomes thick (bottom up) as indicated by white arrows 100.

If the film forming reflow step is sufficiently executed for a long period of time, it is possible to almost completely fill the hole 4B depending on a hole diameter (see FIG. 3E). However, the hole 4B may not be completely filled. In any case, the bottom up is realized by performing the film forming reflow step, so that the generation of a void in the hole 4B can be suppressed. Further, even if the aspect ratio of the recess 4 is increased, the filling operation can be normally carried out. In FIG. 3E, the hole 4B is completely filled with the main film 92, whereas the groove 4A disposed at an upper portion of the hole 4B is not completely filled.

The processing conditions in the film forming reflow step are described as follows.

The processing pressure is preferably in a range from 50 mTorr to 200 mTorr, and more preferably in a range from mTorr to 100 mTorr. Specifically, the processing pressure may be set to, e.g., 90 mTorr.

The high frequency power for plasma generation is preferably in a range from 3 kW to 6 kW, and more preferably in a range from 4 kW to 5 kW. Specifically, the high frequency power for plasma generation may be set to, e.g., 4 kW.

The DC power applied to the target is preferably in a range from 2 kW to 12 kW and more preferably in a range from 3 kW to 6 kW. Specifically, the DC power to the target may be set to, e.g., 5 kW.

The high frequency power for bias is preferably in a range from 300 W to 1000 W. Specifically, the high frequency power for bias may be set to, e.g., 600 W.

The wafer temperature is preferably in a range from 25° C. to 200° C., and more preferably in a range from 50° C. to 100° C. Specifically, the wafer temperature may be set to, e.g., 80° C.

Here, the wafer temperature is preferably in the range from 50° C. to 100° C. to facilitate the reflow of the Cu film, as described above. When the wafer temperature is lower than 25° C., the Cu film is not sufficiently diffused and thus, the possibility in which a void or the like is generated is increased. When the wafer temperature is higher than 200° C., the Cu film becomes excessively soft and thus is diffused intensively. Accordingly, the Cu film on the sidewall of the recess flows into the recess, which is not preferable.

As described above, by setting the processing pressure in the film forming reflow step to be higher than that in the etching step, the downward directivity of Ar ions is increased. Therefore, the main film 92 formed of a Cu film easily flows.

After the film forming reflow step is completed as described above, the wafer W is unloaded from the processing chamber 22 of the processing apparatus 20 to the outside and, then, the recess 4 is completely filled with a thin film 101 made of Cu by performing a copper plating process on the wafer surface as shown in FIG. 3F. Thereafter, as shown in FIG. 3G, the residual thin film 101, the residual main film 92, the residual base film 90, and the residual barrier layer 8 on the wafer surface are removed by a CMP process or the like.

In this case, since the sufficient amount of Cu film is filled in the recess 4, the plating process is completed in a short period of time and the plating process is reduced. Moreover, when the plating process is not required or when the period of time for the plating process is decreased as described above, impurities in the plating solution are prevented from intruding the Cu thin film. Therefore, grains of Cu grow sufficiently by annealing performed in a post step and an electrical resistance can be reduced by that amount.

As described above, in accordance with the embodiment of the present invention, the metal thin film is deposited by generating metal ions by ionizing metal atoms or metal atom groups emitted from the metal target 76 by sputtering the metal target 76 in the vacuum processing chamber 22 and then attracting the metal ions to the wafer W having a recess and mounted on the mounting table 34 in the processing chamber with a bias. At this time, even if the line width or the hole diameter is reduced or the aspect ratio is increased, the metal thin film can be sufficiently deposited in the recess in the surface of the target object (wafer W), and formed in the recess without generating a void by performing the base film formation step, the etching step, and the film forming reflow step.

Since the metal thin film can be sufficiently deposited in the recess, the period of time required for the filling operation performed in the post step by the plating process can be reduced, or the plating process itself may be unnecessary.

<Evaluation on Filling Characteristics in the Film Forming Reflow Step>

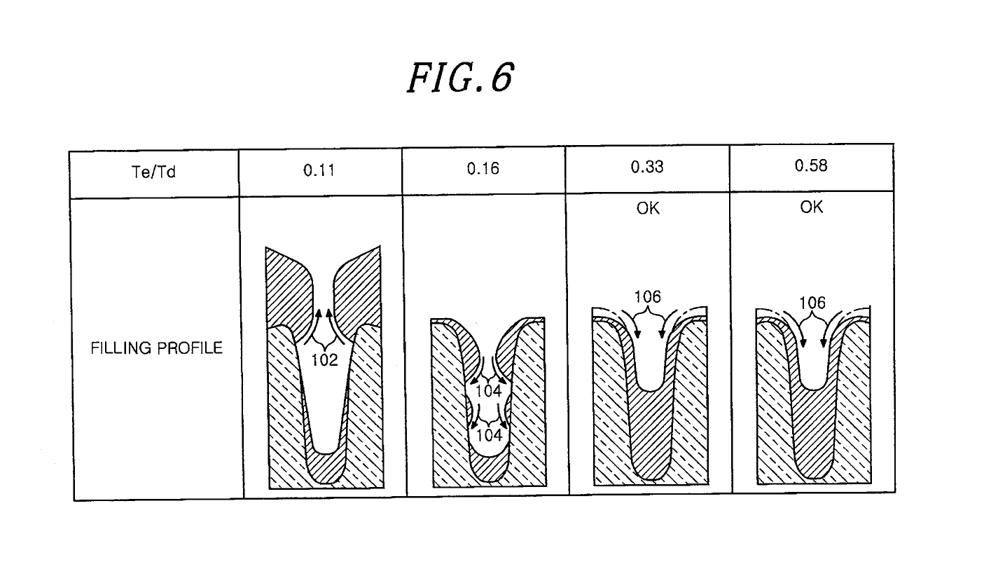

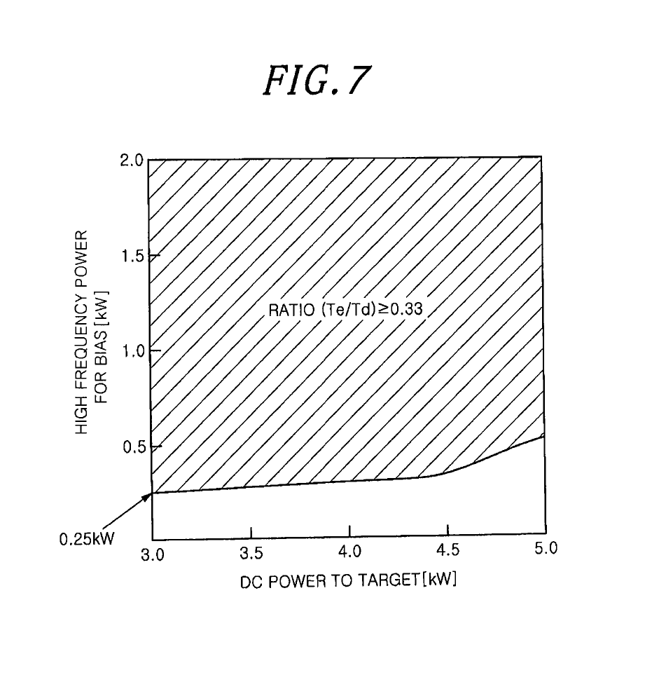

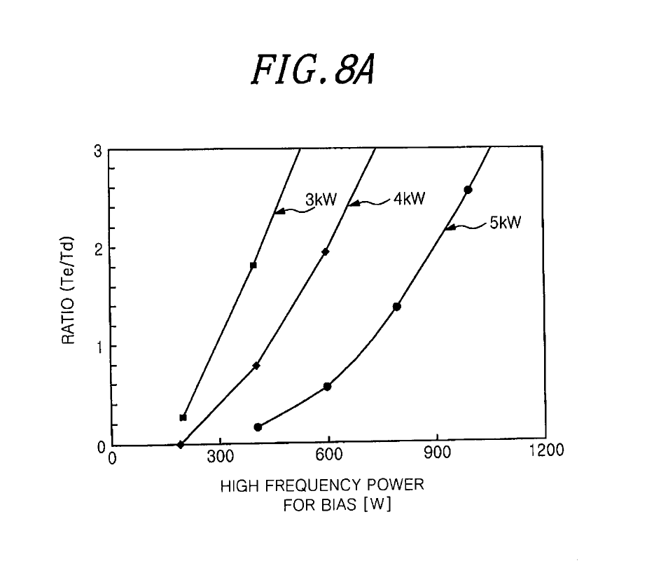

Next, a result of a test on filling characteristics of the recess in the film forming reflow step will be described. FIG. 6 shows the relationship between a filling result and a ratio Te/Td of a maximum film formation amount Td and an etching amount Te, and FIG. 7 is a graph showing a region where the ratio Te/Td is greater than or equal to 0.33.

Here, the filling characteristics of the ratio Te/Td were evaluated, wherein Td indicates a maximum value of film forming amount, which varies depending on a level of a high frequency power for bias and Te indicates an etching amount of the main film 92 formed of a Cu film. The maximum film forming amount Td corresponds to a film forming amount (maximum value) at the point P1 in FIG. 5, and the etching amount is indicated by a difference between Td and the Cu film forming amount in the case of varying the high frequency power for bias.

The ratio Te/Td varies from 0.11 to 0.58. Other processing conditions such as the processing pressure, the high frequency power for plasma generation and the DC power applied to the target are set to 90 mTorr, 4 kW, and 5 kW, respectively. As shown in FIG. 6, when the ratio Te/Td is 0.11, the main film formed of a deposited Cu film is attracted upward in the opening of the recess as indicated by arrows 102 and thus, does not reflow. When the ratio Te/Td is 0.16, the main film as a Cu film partially flows over the sidewall of the recess as indicated by arrows 104 and becomes condensed, which is not preferable.

In contrast, when the ratio Te/Td is 0.33 and 0.58, the main film as a Cu film flows along the sidewall and is diffused into the recess as indicated by arrows 106, which is preferable. Hence, it is clear that the ratio Te/Td is required to be set to 0.33 or above in order to normally perform the film forming reflow step. The ratio Te/Td is changed by the relationship between the high frequency power for bias and the DC power applied to the target and the region where the ratio Te/Td is 0.33 or above corresponds to a region indicated by shaded portions in FIG. 7. Therefore, referring to FIG. 7, it is clear that the DC power applied to the target needs to be at least 3 kW since the high frequency power for bias needs to be 0.25 kW or above.

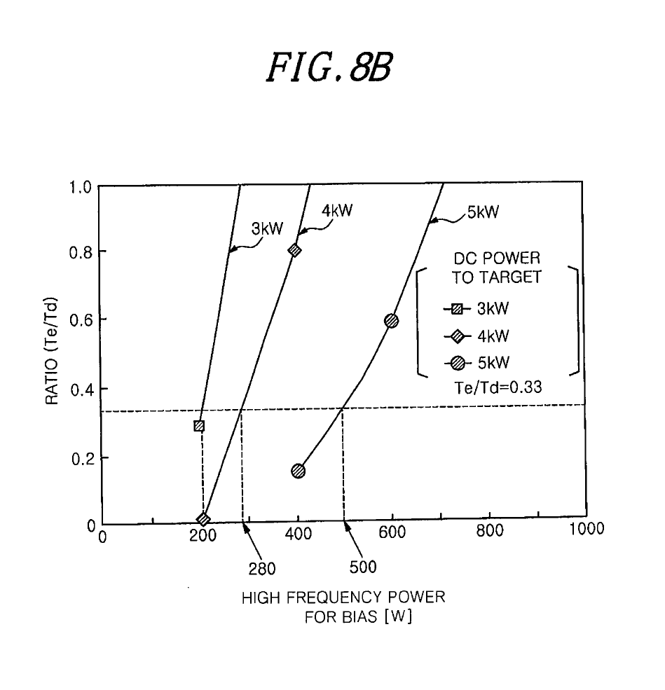

Next, the relationship between the high frequency power for bias and the ratio Te/Td in the case of varying the DC power supplied to the target to 3 kW, 4 kW, and 5 kW was examined in detail. The result thereof is shown in FIGS. 8A and 8B. In these drawings, the horizontal axis indicates the high frequency power for bias and the vertical axis indicates the ratio Te/Td. FIG. 8A shows an entire view, and FIG. 8B shows an enlarged fragment view of FIG. 8A. At this time, the processing conditions such as the processing pressure and the high frequency power for plasma generation are set to 90 mTorr and 4 kW, respectively.

As shown in FIG. 8A, as the high frequency power for bias is increased, the ratio Te/Td is gradually increased. When the high frequency power for bias is maintained at a constant level, the ratio Te/Td is gradually decreased as the DC power applied to the target is increased. Since the ratio Te/Td is set to 0.33 or above, it is clear that when the DC power supplied to the target is 3 kW, 4 kW, and 5 kW, the high frequency power for bias is set to 200 W or above, 280 W or above, and 500 W or above, respectively, as shown in FIG. 8B.

<Second Embodiment of the Film Forming Method of the Present Invention>

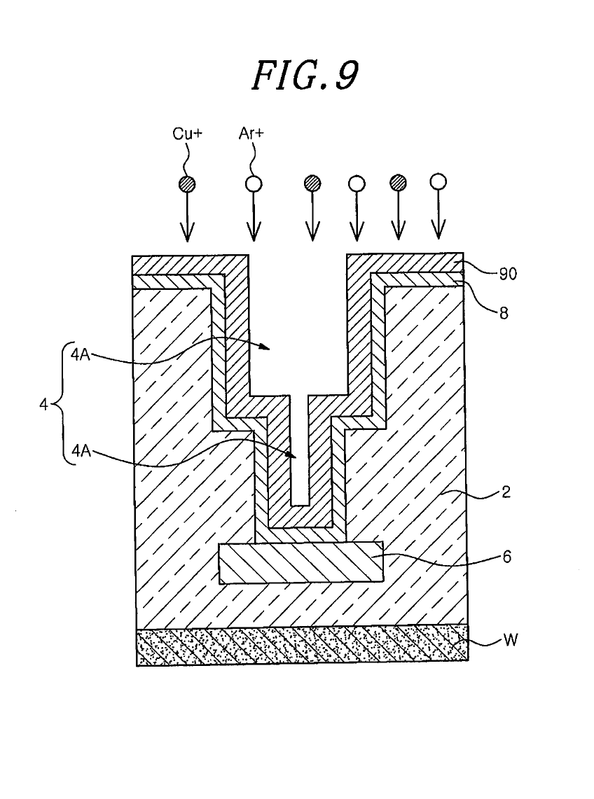

Next, a second embodiment of the film forming method of the present invention will be described. In the first embodiment described with reference to FIGS. 3A to 3G, the base film 90 having a sufficient thickness is formed especially on the sidewall portion in the hole 4B of the recess 4, so that the two steps including the base film forming step (see FIG. 3C) and the etching step (see FIG. 3D) are carried out. However, only a film forming and etching step may be carried out instead of the above two steps. In the film forming and etching step, the base film is formed by attracting metal ions toward the wafer with a bias and etched. FIG. 9 explains the film forming and etching step in accordance with the second embodiment of the film forming method of the present invention.

In the film forming and etching step, the film formation by Cu ions is performed together with the etching by Ar ions. Specifically, the high frequency power for bias in the film forming and etching step is set to be higher than that in the base film forming step in accordance with the first embodiment. Specifically, the film forming and etching step is performed at a high frequency power for bias in a region A3 in FIG. 5, i.e., a region positioned at a left side of the point P2. Accordingly, the base film 90 as a Cu film is formed on the surface of the wafer W, especially on the surface facing upward. Also, the base film 90 deposited on the portion where the base film 90 is thickly formed, i.e., the bottom surface of the hole 4B or the bottom surface of the groove 4A, is etched intensively. The metal particles scattered by the etching are deposited on the sidewall of the recess 4, especially on the sidewall of the hole 4B, thereby increasing the thickness of the base film 90 deposited on the sidewall portions, as described with reference to FIG. 3D and FIG. 4B.

The processing conditions in the film forming and etching step are described as follows.

The processing pressure is preferably in a range from 50 mTorr to 200 mTorr, and more preferably in a range from mTorr to 100 mTorr. Specifically, the processing pressure may be set to, e.g., 90 mTorr.

The high frequency power for plasma generation is preferably in a range from 3 kW to 6 kW, and more preferably in a range from 4 kW to 5 kW. Specifically, the high frequency power for plasma generation may be set to, e.g., 4 kW.

The DC power applied to the target is preferably in a range from 4 kW to 20 kW and more preferably in a range from 8 kW to 12 kW. Specifically, the DC power to the target may be set to, e.g., 10 kW.

The high frequency power for bias is preferably in a range from 400 W to 2000 W and more preferably in a range from 400 W to 1200 W. Specifically, the high frequency power for bias may be set to, e.g., 1000 W.

The wafer temperature is preferably in a range from 25° C. to 200° C. and more preferably in a range from 25° C. to 100° C. Specifically, the wafer temperature may be set to, e.g., 50° C.

Upon completion of the film forming and etching step, the film forming reflow step described in FIG. 3E, the plating step described in FIG. 3F, and the CMP process described in FIG. 3G are carried out. As described in the first embodiment, the plating step may be omitted. In the second embodiment as well, the same effect as that of the first embodiment can be realized.

In the above embodiments, the barrier layer 8 has a laminated structure of a TiN film and a Ti film. However, the structure of the barrier layer 8 is not limited thereto and may be a single layer structure or a laminated structure including one or more films selected from a group consisting of a Ti film, a TiN film, a Ta film, a TaN film, a TaCN film, a W (tungsten) film, a WN film, and a Zr film.

In the above embodiments, the recess 4 having a two-stage structure including the groove 4A and the hole 4B has been described an example. However, the present invention is not limited thereto and may also be applied to a recess having a so-called single layer structure simply formed of a groove or a hole.

The frequency of the high frequency power supply is not limited to 13.56 MHz and may employ another frequency. For example, a high frequency ranging from 400 kHz to 60 MHz is preferably employed, and a high frequency ranging from 400 kHz to 27.0 MHz is more preferably employed. Further, the rare gas for plasma is not limited to Ar gas, and may be another rare gas such as He, Ne, or the like, or a rare gas added with hydrogen.

Here, the semiconductor wafer has been described as an example of the target object. This semiconductor wafer includes a silicon substrate or a compound semiconductor substrate such as GaAs, SiC, GaN or the like. Further, the present invention may also be applied to a ceramic substrate or a glass substrate used for a liquid display device without being limited to the above semiconductor substrates.

While the invention has been shown and described with respect to the embodiments, the present invention is not limited to the above-described embodiments and various changes and modifications may be made without departing from the scope of the invention as defined in the following claims.

This application claims priority to Japanese Patent Application No. 2010-217895 filed on Sep. 28, 2010, the entire contents of which are incorporated herein by reference.

What is claimed is:

1. A film forming method for depositing a metal thin film in a recess formed in a target object, which is mounted on a mounting table in a vacuum processing chamber, by attracting metal ions into the target object by supplying a high frequency power for bias to the mounting table to apply a bias to the target object, the metal ions being generated by ionizing a metal target by a plasma in the processing chamber, the method comprising:
a base film forming step of forming a base film containing the metal in the recess by attracting the metal ions into the target object with the bias;
an etching step of etching the base film by attracting ions of a rare gas into the target object, the ions of the rare gas being generated by ionizing the rare gas by generating a plasma in a state where the metal ions are not generated while applying the bias to the target object; and
a film formation reflow step of depositing a main film as a metal film by attracting ions of the metal into the target object with the bias applied to the target object while reflowing the main film by heating.

2. The film forming method of claim 1, wherein the high frequency power for bias in the etching step is larger than the high frequency power for bias in the base film forming step.

3. The film forming method of claim 1, wherein a pressure of the processing chamber in the etching step is lower than a pressure of the processing chamber in the base film forming step.

4. The film forming method of claim 1, wherein a pressure of the processing chamber in the film formation reflow step is higher than a pressure of the processing chamber in the etching step.

5. The film forming method of claim 1, wherein in the etching step, a DC power applied to the metal target is set to 0, and a high frequency power for generating the metal ions is set to 0.

6. The film forming method of claim 1, wherein in the film formation reflow step, a ratio Te/Td of a maximum film forming amount Td and a main film etching amount Te is set to 0.33 or above, under a predetermined high frequency power for bias.

7. The film forming method of claim 1, wherein in the film formation reflow step, a temperature of the target object is set within a range from 25° C. to 200° C.

8. The film forming method of claim 1, wherein the respective steps are performed in the same processing chamber.

9. The film forming method of claim 1, wherein the metal is copper.

10. The film forming method of claim 1, wherein a plating step of filling the metal in the recess by plating is performed after the film formation reflow step.

11. A film forming method for depositing a metal thin film in a recess formed in a target object, which is mounted on a mounting table in a vacuum processing chamber, by metal ions into the target object by supplying a high frequency power for bias to the mounting table to apply a bias to the target object, the metal ions being generated by ionizing a metal target by a plasma in the processing chamber, the method comprising:
a film forming and etching step of forming a base film containing the metal in the recess by attracting the metal ions into the target object with the bias while etching the base film; and
a film formation reflow step of depositing a main film as a metal film by attracting the metal ions into the target object with the bias while reflowing the main film by heating.

12. The film forming method of claim 11, wherein in the film forming reflow step, a ratio Te/Td of a maximum film forming amount Td and a main film etching amount Te is set to 0.33 or above, under a predetermined high frequency power for bias.

13. The film forming method of claim 11, wherein in the film forming reflow step, a temperature of the target object is set within a range from 25° C. to 200° C.

14. The film forming method of claim 11, wherein the respective steps are performed in the same processing chamber.

15. The film forming method of claim 11, wherein the metal is copper.

16. The film forming method of claim 11, wherein a plating step of filling the metal in the recess by plating is performed after the film forming reflow step.

17. A film forming apparatus comprising:
a vacuum processing chamber;
a mounting table for mounting thereon a target object having a recess;
a gas introducing unit for introducing a predetermined gas into the processing chamber;
a plasma generation source for generating a plasma in the processing chamber;
a metal target provided in the processing chamber to be ionized by the plasma;
a high frequency power supply for supplying a high frequency power for bias to the mounting table; and
an apparatus controller for controlling the entire apparatus to perform the film forming method described in claim 1.

18. A film forming apparatus comprising:
a vacuum processing chamber;
a mounting table for mounting thereon a target object having a recess;
a gas introducing unit for introducing a predetermined gas into the processing chamber;
a plasma generation source for generating a plasma in the processing chamber;
a metal target provided in the processing chamber to be ionized by the plasma;
a high frequency power supply for supplying a high frequency power for bias to the mounting table; and
an apparatus controller for controlling the entire apparatus to perform the film forming method described in claim 11.
